(19) United States
(12) Patent Application Publication
(10) Pub. No.: US 2024/0387778 A1
(43) Pub. Date: Nov. 21, 2024

(54) LIGHT-EMITTING SEMICONDUCTOR CHIP AND METHOD FOR PRODUCING A LIGHT-EMITTING SEMICONDUCTOR CHIP

(71) Applicant: ams-OSRAM International GmbH, Regensburg (DE)

(72) Inventors: Laura KREINER, Regensburg (DE); Wolfgang SCHMID, Kelheim (DE)

(73) Assignee: ams-OSRAM International GmbH, Regensburg (DE)

(21) Appl. No.: 18/691,954

(22) PCT Filed: Sep. 16, 2022
(86) PCT No.: PCT/EP2022/075761

§ 371 Date: Mar. 14, 2024

(30) Foreign Application Priority Data
Sep. 17, 2021 (DE) 10 2021 124 146.4

(51) Int. Cl. H01L 33/38; H01L 33/00; H01L 33/22; H01L 33/46

(52) U.S. Cl. CPC H01L 33/382; H01L 33/0095; H01L 33/465; H01L 33/22; H01L 2933/0016; H01L 2933/0025; H01L 2933/0083

(57) ABSTRACT

The invention relates to a semiconductor light emitting chip including a semiconductor layer sequence having an active layer which is provided and arranged to generate light when in operation and to couple out via a light outcoupling surface, a filter layer deposited on the light outcoupling surface, and a contact structure deposited on the light outcoupling surface in a region free of the filter layer. The invention also relates to a method for producing said light-emitting semiconductor chip.

### CROSS-REFERENCE TO RELATED APPLICATIONS

The present application is a national stage entry from International Application No. PCT/EP2022/075761, filed on Sep. 16, 2022, published as International Publication No. WO 2023/041704 A1 on Mar. 23, 2023, and claims priority to German Patent Application No. 10 2021 124 146.4, filed Sep. 17, 2021, the disclosures of all of which are hereby incorporated by reference in their entireties.

### FIELD

A light-emitting semiconductor chip and a method for manufacturing a light-emitting semiconductor chip are specified.

### BACKGROUND

For example in applications in the fields of projection, sensing, etc., light can often only be used in a certain angular range. However, typical light-emitting diodes (LEDs) have a Lambertian radiation characteristic. It is therefore desirable to change the radiation characteristics so that light is emitted directly away from the component only within a desired angular range. For example, the publication EP 1 887 634 A1 describes a device in which a separately manufactured filter element based on backward-directed concentrators is mounted on or over an LED chip. However, a more compact design is desirable, particularly for applications that are delimited by the available installation space. LEDs based on InAlGaP and/or InAlGaAs, which emit in the red or infrared wavelength range, also usually have contact webs on the chip surface in order to distribute the current over the entire chip. As back reflection on the contact webs leads to considerable losses, an element that influences the radiation characteristics cannot be easily applied to the component surface.

At least one object of particular embodiments is to provide a light-emitting semiconductor chip. At least one further object of particular embodiments is to provide a method for manufacturing a light-emitting semiconductor chip.

These objects are achieved by a subject-matter and a method according to the independent claims. Advantageous embodiments and developments of the subject-matter and the method are characterized in the dependent claims, and are also disclosed by the following description and the drawings.

### SUMMARY

According to at least one embodiment, a light-emitting semiconductor chip has a semiconductor layer sequence with an active layer which is intended and configured to generate light during operation.

According to at least one further embodiment, in a method for manufacturing a light-emitting semiconductor chip, a semiconductor layer sequence is provided with an active layer which is intended and configured to generate light during operation of the light-emitting semiconductor chip.

The embodiments and features described below equally apply to the light-emitting semiconductor chip and to the method for manufacturing the light-emitting semiconductor chip.

The semiconductor layer sequence can be provided by being grown on a growth substrate by means of an epitaxy process, for example by means of metal-organic vapor-phase epitaxy (MOVPE) or molecular-beam epitaxy (MBE). The semiconductor layer sequence thus has semiconductor layers that are arranged on top of each other along an arrangement direction that is given by the growth direction. Perpendicular to the arrangement direction, the layers of the semiconductor layer sequence have a main extension plane. Directions parallel to the main extension plane of the semiconductor layers and thus perpendicular to the growth direction are referred to as lateral directions in the following.

In particular, the semiconductor layer sequence has two main surfaces that are arranged perpendicular to the direction of growth. One of the main surfaces is embodied as a light-outcoupling surface, via which the light generated during operation of the light-emitting semiconductor chip is decoupled from the semiconductor layer sequence. Furthermore, the semiconductor layer sequence has a rear surface opposite the light-outcoupling surface, which can form a second main surface of the semiconductor layer sequence. The light-outcoupling surface and the rear surface are connected to each other via side surfaces.

Depending on the light to be generated, the light-emitting semiconductor chip can have a semiconductor layer sequence based on different semiconductor material systems. For example, a semiconductor layer sequence based on InₓGa_{y}Al_{1-x-y}As is suitable for long-wave infrared to red radiation, a semiconductor layer sequence based on InₓGa_{y}Al_{1-x-y}P is suitable for red to yellow radiation, and a semiconductor layer sequence based on InₓGa_{y}Al_{1-x-y}N is suitable, for example, for short-wave visible radiation, i.e., in particular for green to blue radiation and/or for UV radiation, wherein in each case 0≤x≤1 and 0≤y≤1 applies. Furthermore, a semiconductor layer sequence based on an antimonide, for example InSb, GaSb, AlSb or a combination thereof, can be suitable for long-wave infrared radiation.

The semiconductor layer sequence of the light-emitting semiconductor chip can, for example, have a conventional p-n junction, a double heterostructure, a single quantum well structure (SQW structure) or a multiple quantum well structure (MOW structure) as the active layer. In addition to the active layer, the semiconductor layer sequence can have further functional layers and functional regions, such as p-or n-doped charge carrier transport layers, undoped or p- or n-doped confinement, cladding or waveguide layers, barrier layers, planarization layers, buffer layers, protective layers and/or contact layers, as well as combinations thereof. Furthermore, viewed from the active layer, on a side opposite the light-outcoupling surface a mirror layer with one or more reflective layers or layer stacks may be present, which reflects light that is emitted in the direction opposite to the light-outcoupling surface back towards the light-outcoupling surface. Furthermore, the light-emitting semiconductor chip can have electrical contacts on the light-outcoupling surface and the rear surface for electrical contacting, via which an electrical current can be injected into the semiconductor layer sequence and thus into the active layer to operate the light-emitting semiconductor chip.

The growth substrate may comprise or be an insulator material or a semiconductor material, for example a compound semiconductor material system as mentioned above. In particular, the growth substrate may comprise or be made of sapphire, GaAs, GaP, GaN, InP, SiC, Si and/or Ge.

In particular, the growth process can take place in a wafer composite. In other words, a growth substrate is provided in the form of a wafer onto which the semiconductor layer sequence is grown across a large area.

Furthermore, the semiconductor layer sequence can be transferred to a carrier substrate before singulation, and the growth substrate can be thinned, i.e., at least partially or completely removed. A reflective layer can be arranged between the carrier substrate and the semiconductor layer sequence, which can improve the radiation efficiency. The reflective layer can, for example, be applied to the semiconductor layer sequence before the semiconductor layer sequence is transferred to the carrier substrate, so that the semiconductor layer sequence with the reflective layer can be mounted on the carrier substrate.

The semiconductor layer sequence, for example on the carrier substrate, can be singulated into individual semiconductor chips in a further process step, whereby the side surfaces of the semiconductor chips can be formed by the singulation. Furthermore, mesa trenches can be formed in the semiconductor layer sequence, along which singulation of the wafer composite into a plurality of light-emitting semiconductor chips can be carried out in a further process step.

According to a further embodiment, the light-emitting semiconductor chip has a filter layer on the light-outcoupling surface. The filter layer is particularly preferably deposited on the light-outcoupling surface. In particular, this can mean that the filter layer is not produced as a separate element separate from the light-emitting semiconductor chip and is then applied and fixed to the light-outcoupling surface, but that the filter layer is produced by deposition on the light-outcoupling surface as an integral component of the light-emitting semiconductor chip. For example, the filter layer can be deposited and produced on the light-outcoupling surface with or by a deposition process which comprises or is a physical vapor deposition process and/or a chemical vapor deposition process, such as evaporation, sputtering, ion plating, waxing.

According to a further embodiment, the filter layer is a dielectric angle filter. For example, the filter layer may be a filter based on or in the form of a Bragg mirror, which may also be referred to as a DBR (distributed Bragg reflector) and which has a periodic sequence of at least two dielectric layers with different refractive indices. For example, several pairs of a first and a second layer with different refractive indices can be arranged one above the other. Furthermore, the filter layer can also have a complicated layer sequence with more than two different types of layer. In particular, the filter layer may, for example, have a sequence of several layers whose materials and layer thicknesses are individually adjusted so that the filter layer has a desired angular selectivity. The arrangement of the layers can also be non-periodic. The layers can each have a material such as an oxide, nitride or oxynitride, for example one or more selected from silicon oxide, silicon nitride, silicon oxynitride, niobium oxide, aluminum oxide, titanium oxide and tantalum oxide. The layers of the filter layer can each have a layer thickness, in particular an optical layer thickness, which is preferably selected as a function of the wavelength of the light generated in the active layer and the refractive index of the material used in each case such that the filter layer has the effect that instead of the radiation characteristic at the light-outcoupling surface, which can in particular be a Lambertian radiation characteristic, there is a more forward-directed radiation characteristic downstream of the filter layer. The filter layer can transmit the light generated in the semiconductor layer sequence, for example, in an angular range of +/−45° or +/−30° or +/−15° or even less to the surface normal and reflect it outside such an angular cone. Through back reflection in the semiconductor layer sequence and an angular redistribution at the light-outcoupling surface, the light can then impinge on the filter layer in a further circulation in the target angle range and be transmitted there.

According to a further embodiment, the light-emitting semiconductor chip has an electrical contact structure which is deposited on the light-outcoupling surface in a region that is free of the filter layer. The electrical contact structure can also be referred to simply as the contact structure in the following. Particularly preferably, the contact structure can be applied directly to the semiconductor layer sequence. The contact structure can, for example, be applied to the light-outcoupling surface by vapor deposition, sputtering or another deposition process and can be intended and configured for electrical contacting and thus a current injection in the semiconductor layer sequence from the light-outcoupling surface during operation of the light-emitting semiconductor chip. Particularly preferably, the contact structure can form a current distribution structure in order to achieve the most uniform possible current distribution into the semiconductor layer sequence from the side of the light-outcoupling surface. For this purpose, the contact structure can preferably have a plurality of contact webs. Furthermore, the contact structure can have a connection region via which the contact structure can be contacted from the outside and which is connected to the contact webs. For example, the connection region can be intended and configured to be contacted by one or more bonding wires. The connection region can thus be a bonding pad, for example, onto which one or more bonding wires can be bonded.

According to a further embodiment, the contact webs are covered by the filter layer on a side facing away from the semiconductor layer sequence. In this case, the contact structure is deposited before the filter layer on the light-outcoupling surface, which is thus free of the filter layer at the time of deposition of the contact structure. Because the filter layer is applied after the contact structure, the filter layer can cover the contact webs and thus form a protective layer for the contact webs. Alternatively, the contact webs can be at least partially free of the filter layer on a side facing away from the semiconductor layer sequence. For this purpose, the filter layer can be at least partially removed from the contact webs.

According to a further embodiment, the contact structure is deposited on the light-outcoupling surface after the filter layer. In order to be able to apply the contact structure, particularly preferably directly, to the light-outcoupling surface in this case, the filter layer is either applied in a structured manner or preferably structured after application across a large area in such a way that the material of the filter layer is removed in the region in which the contact structure is to be applied.

In particular, the connection region is at least partially free of the filter layer on a side facing away from the semiconductor layer sequence, so that the connection region and thus the contact structure for the external contacting described above is freely accessible.

For the structured application of a layer or structure or for structuring a layer after application across a large area, photo-techniques and mask-based structuring processes can be used in particular, which can include, for example, photolithography processes and/or wet and/or dry chemical etching processes and/or lift-off processes and/or light-based ablation processes.

According to a further embodiment, the semiconductor layer sequence has a light-outcoupling structure on the light-outcoupling surface. The light-outcoupling structure, which may for example have regularly and/or randomly distributed elevations and/or depressions, can for example avoid or at least reduce waveguide effects in the semiconductor layer sequence. The light-outcoupling structure can have elevations and/or depressions with dimensions in the range from a few hundred nanometers to several micrometers, which can be produced, for example, by etching the light-outcoupling surface. The semiconductor layer sequence is particularly preferably provided with the light-outcoupling structure. This light-outcoupling structure can additionally have the function of scattering light that has been reflected back into the semiconductor chip at the filter layer and thereby impinges on the filter layer in the desired angular range after one or more reflections within the semiconductor chip and is then transmitted. Furthermore, it is also possible that, in addition or as an alternative to a light-outcoupling structure on the light-outcoupling surface, a scattering layer is provided at a different location between a rear-side mirror layer seen from the active layer in relation to the light-outcoupling surface and the light-outcoupling surface.

According to a further embodiment, a planarization layer is applied to the light-outcoupling surface. In a particularly preferred embodiment, the planarization layer is applied directly to the light-outcoupling surface and in particular to the light-outcoupling structure. The planarization layer can, for example, comprise or be made of an oxide, nitride or oxynitride. It is particularly preferred to use a material for the planarization layer that is transparent and has a refractive index that is lower than the refractive index of the semiconductor layer sequence at the light-outcoupling surface. For example, the planarization layer has silicon oxide or is made of silicon oxide. The planarization layer preferably has a thickness that is greater than the height differences of the light-outcoupling structure, so that the light-outcoupling structure is completely covered by the planarization layer. To produce the planarization layer, chemical vapor deposition, for example with TEOS (tetraethyl orthosilicate) or silane, a sputtering process or a spin-on process, for example with spin-on-glass, can be used. Other deposition processes are also possible. The deposited material can then be polished, for example using a chemical-mechanical polishing method (CMP method), so that the surface of the planarization layer facing away from the semiconductor layer sequence is as flat as possible.

In particular, the filter layer is arranged on the planarization layer. For example, the filter layer can be applied directly to the planarization layer. Alternatively, a passivation layer, for example with or made of silicon nitride and/or another nitride, oxide and/or oxynitride, can be applied, preferably directly, to the planarization layer. In this case, the filter layer can be applied, preferably directly, to the passivation layer. Furthermore, alternatively or additionally, a passivation layer can also be applied, preferably directly, to the filter layer and or directly to the semiconductor layer sequence.

The planarization layer or the planarization layer and the passivation layer are preferably applied across a large area of the light-outcoupling surface before the filter layer and the contact structure are applied. If the filter layer is applied before the contact structure, this is also preferably applied across a large area as described above. In order to be able to apply the contact structure, preferably directly, to the light-outcoupling surface, the layers already applied to the light-outcoupling surface are structured in such a way that an opening is made in them in the region where the contact structure is to be applied. The opening thus essentially forms a contiguous negative shape to the contact structure to be applied. Consequently, depending on the layers already present, the contact structure is arranged, for example, in an opening in the planarization layer or in an opening in the planarization layer and the passivation layer or in an opening in the planarization layer, the filter layer and the passivation layer.

The opening in which the contact structure is applied can be larger than the contact structure in terms of its lateral expansion, so that the contact structure is spaced laterally from the planarization layer or from the planarization layer and the passivation layer or from the planarization layer, the filter layer and the passivation layer, for example, depending on the layers already present. Thus, after application of the contact structure, there may be a gap between the contact structure and the layer or layers already present on the light-outcoupling surface before application of the contact structure. The light-outcoupling surface can thus be exposed in the opening in a region between the contact structure and the planarization layer or between the contact structure and the planarization layer and the passivation layer or between the contact structure and the planarization layer, the filter layer and the passivation layer. If the filter layer is applied after the contact structure, it can be applied directly to the light-outcoupling surface in the space between the contact structure and the planarization layer. Furthermore, it may also be possible for the contact structure to be applied with a width, i.e., a greater lateral expansion, which is equal to or greater than the lateral expansion of the opening and can thus completely fill the opening and even protrude beyond it in the lateral direction. As a result, the contact structure can protect the semiconductor material, which would be accessible through the opening, from external influences and thus have a passivation function. Furthermore, it may be possible to reduce the proportion of oblique light that is coupled out.

According to further embodiments, one, several or even all of the following process steps can preferably be carried out to produce the light-emitting semiconductor chip, which can be further developed or modified according to the precedingly described embodiments and features:
Providing a semiconductor layer sequence provided on a substrate, particularly preferably a carrier substrate, which has, for example, a light-outcoupling structure produced by roughening etching on the light-outcoupling surface and/or a scattering layer
Applying and polishing a planarization layer, which can preferably be an oxide layer, for example of SiO₂ using TEOS and CMP, to planarize the light-outcoupling surface
Mesa etching and passivation by applying a passivation layer, for example of Si₃N₄
Opening of the planarization layer in the region of the contact structure to be applied, for example by wet-chemical etching
Applying a contact structure, preferably with a plurality of contact webs and a connection region
Applying a filter layer, preferably an angle-selective filter layer, for example made of alternating layers of SiO₂ and Nb₂O₅
Opening of the filter layer, at least in the region and preferably only in the region of the connection region of the contact structure

According to further embodiments, one, several or even all of the following process steps can preferably be carried out to produce the light-emitting semiconductor chip, which can be further developed or modified according to the previously described embodiments and features:
Providing a semiconductor layer sequence provided on a substrate, particularly preferably a carrier substrate, which particularly preferably has a light-outcoupling structure produced by roughening etching on the light-outcoupling surface
Applying and polishing a planarization layer, which can preferably be an oxide layer, for example of SiO: using TEOS and CMP, to planarize the light-outcoupling surface
Applying a filter layer, preferably an angle-selective filter layer, for example made of alternating layers of SiO₂ and Nb₂O₅
Mesa etching and passivation by applying a passivation layer, for example of Si₃N₄
Opening of the filter layer and the planarization layer in the region of a contact structure to be applied, for example by means of dry-chemical etching and/or wet-chemical etching
Applying the contact structure, preferably with a plurality of contact webs and a connection region

In the light-emitting semiconductor chip and the method for manufacturing the light-emitting semiconductor chip described herein, a preferably angle-selective element in the form of the filter layer for adapting the radiation characteristics can be formed as an integral component of the semiconductor chip. In particular, the filter layer can be integrated together with a contact structure on the light-outcoupling surface so that, unlike described in the prior art, no additional pre-fabricated element influencing the radiation characteristics has to be mounted on the semiconductor chip, which could lead to problems in interaction with the contact structure. This means that directional emission is possible without an additional optical element, even with light-emitting semiconductor chips that have a contact structure on the light-outcoupling surface.

Further advantages, advantageous embodiments and further developments are revealed by the embodiments described below in connection with the figures.

### BRIEF DESCRIPTION OF THE DRAWINGS

FIG. 1 shows a schematic illustration of a method step of a method for manufacturing a light-emitting semiconductor chip according to an embodiment,

FIG. 2 shows a schematic illustration of a method step of a method for manufacturing a light-emitting semiconductor chip according to a further embodiment,

FIGS. 3A and 3E show schematic illustrations of method steps of a method for manufacturing a light-emitting semiconductor chip according to a further embodiment,

FIG. 4 shows a schematic illustration of a light-emitting semiconductor chip according to a further embodiment,

FIGS. 5A and 5E show schematic illustrations of method steps of a method for manufacturing a light-emitting semiconductor chip according to a further embodiment and

FIGS. 6A to 7B show schematic illustrations of method steps of a method for manufacturing a light-emitting semiconductor chip according to further embodiments.

### DETAILED DESCRIPTION

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

Various embodiments are shown in the figures, by means of which method steps of a method for manufacturing a light-emitting semiconductor chip 100 and the light-emitting semiconductor chip comprising a filter layer and a contact structure on a light-outcoupling surface are explained.

In a first process step, as shown in FIG. 1, a semiconductor layer sequence 1 is provided which has an active layer 10 which is intended and configured to generate light during operation. The light generated during operation can be decoupled via a light-outcoupling surface 11. The semiconductor layer sequence 1 can particularly preferably be grown on a growth substrate by means of an epitaxy process such as MOVPE. Purely by way of example, the finished light-emitting semiconductor chip can be a red light-emitting or infrared light-emitting semiconductor chip based on a compound semiconductor material system based on InAlGaAs or InAlGaP. Alternatively, the light-emitting semiconductor chip can also be based on another semiconductor material and/or be intended and configured to generate light with a different wavelength, as described in the general part. The arrangement direction of the semiconductor layers of the semiconductor layer sequence 1, i.e., the growth direction, corresponds in the illustration shown to a direction parallel to the vertical direction. Directions perpendicular to the growth direction, i.e., horizontal directions in the illustration shown, are referred to below as lateral directions.

The production and thus the provision of the semiconductor layer sequence 1 and also the process steps described below are preferably carried out in a wafer composite, which is shown in a section in FIG. 1 and in the following figures. The growth substrate is provided in the form of a wafer on which the semiconductor layer sequence 1 is grown across a large area. After the process steps described below have been carried out, the wafer composite can be separated into individual light-emitting semiconductor chips. Singulation lines 99 are therefore indicated in the figures, at which such singulation is carried out, for example, by sawing and/or etching and/or laser separation.

By way of example only, in the process steps described in connection with the figures, a so-called thin film semiconductor chip is produced, in which the semiconductor layer sequence 1 is transferred to a carrier substrate 2 after growth and the growth substrate is at least thinned or, in the present embodiment, removed, so that, as shown in FIG. 1, the light-outcoupling region opposite the carrier substrate 2 is formed by a surface of the semiconductor layer sequence 1. A light-outcoupling structure 12 is formed in the light-outcoupling surface, for example by roughening etching, as described in the general section.

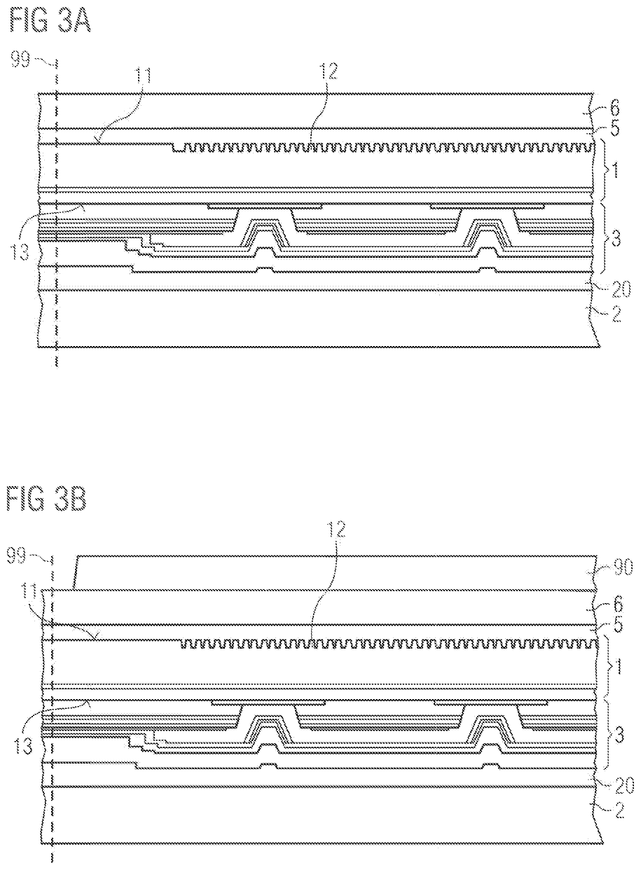

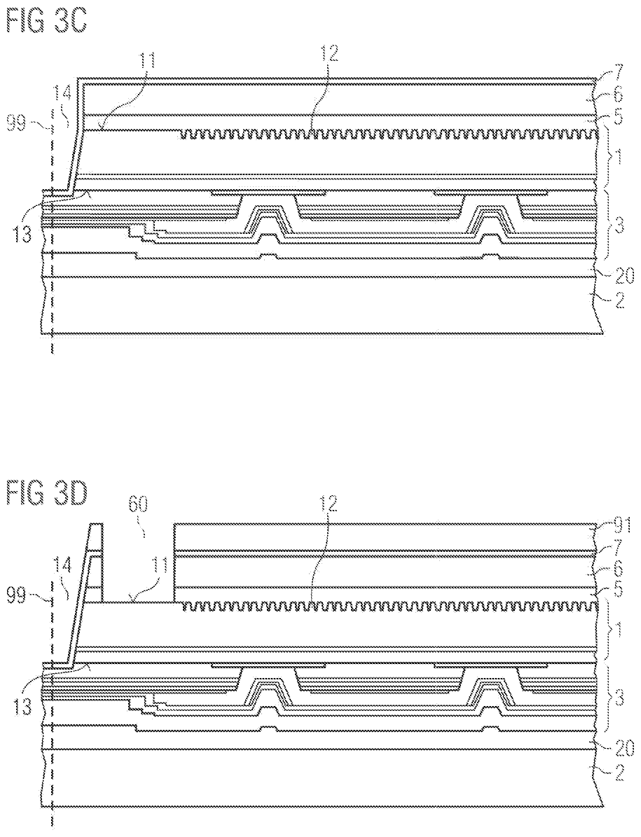

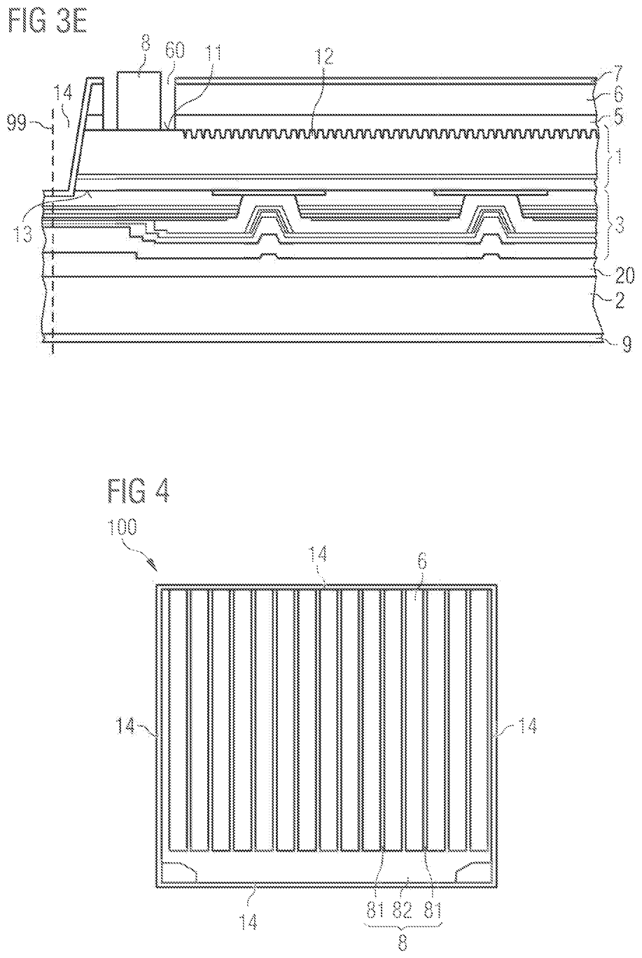

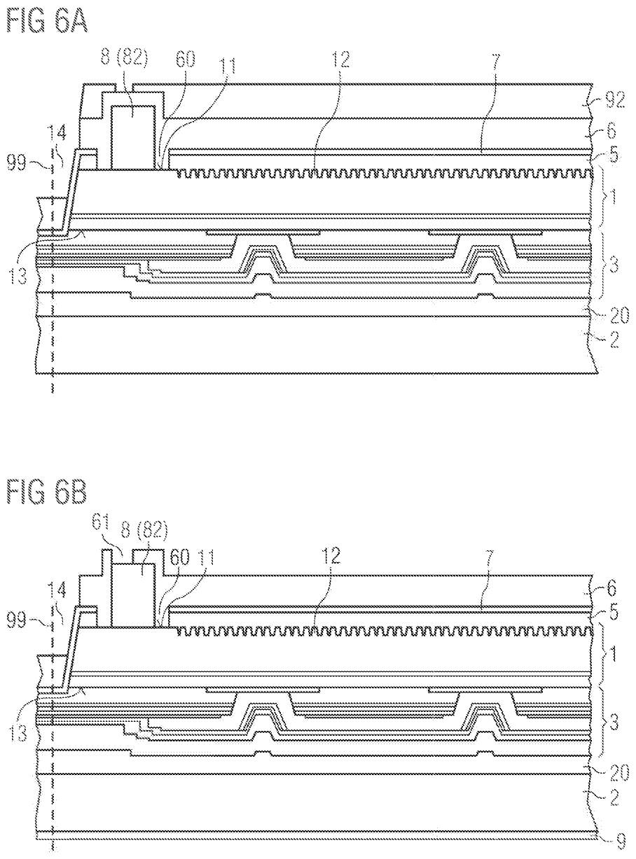

The carrier substrate 2 is arranged on the main surface of the semiconductor layer sequence opposite the light-outcoupling surface 11, which forms a rear surface 13 of the semiconductor layer sequence, and may for example comprise or be made of silicon. Other materials are also possible, with the carrier substrate 2 preferably being electrically conducting, so that, as shown in FIGS. 3E and 6B, electrical contacting of the semiconductor layer sequence 1 from the rear surface 13 can be made via a contact layer 9 on the side of the carrier substrate 2 facing away from the semiconductor layer sequence 1. For mounting on the carrier substrate 2, for example, a solder layer 20 can be used.

For high efficiency of the light-emitting semiconductor chip, high reflectivity is required on the rear side of the semiconductor layer sequence 1 opposite the light-outcoupling surface 11, especially for light that is incident at a large angle to the surface normal. A combination of a dielectric mirror and a metal mirror, for example, is suitable for this purpose. Therefore, a reflective layer 3 with vias 4 is located on the rear surface of the semiconductor layer sequence, by means of which the semiconductor layer sequence 1 is mounted on the carrier substrate 2 via the solder layer 20. The reflective layer 3 is applied to the semiconductor layer sequence 1 before it is transferred to the carrier substrate 2 and has a Bragg mirror 31 which is applied across a large area on the rear surface 13 and which has a high reflectivity for the light generated in the semiconductor layer sequence 1 during operation. For red or infrared light, for example, a layer sequence with several layer pairs with layers of silicon dioxide and niobium pentoxide can be advantageous. On the side of the Bragg mirror 31 facing away from the semiconductor layer sequence 1, a metallic mirror layer 32 is applied, which may, for example, be with or made of silver and/or gold. As an adhesion promoter, an adhesion promoter layer 33, for example with or made of aluminum oxide, is arranged between the Bragg mirror 31 and the metallic mirror layer 32, which is preferably applied by means of atomic layer deposition. This also enables a high level of impermeability to moisture to be achieved.

The Bragg mirror 31 and the adhesion promoter layer 33 are structured and have openings through which the metallic mirror layer 32 protrudes. This forms the vias 4 to the rear surface 13 of the semiconductor layer sequence 1. Contact layers 40 made of a transparent conducting oxide, such as indium tin oxide, are arranged sectionally on the vias 4, which establish an electrical connection to the rear surface 13 of the semiconductor layer sequence 1. The vias 4 typically have a dimension of a few micrometers, for example 5 μm, in the lateral direction, while the contact layers 40 can have a larger dimension of 10 μm or more, for example 25 μm. As can be seen in FIG. 1, the Bragg mirror 31 is applied between and above the contact layers 40 as viewed from the semiconductor layer sequence 1.

On the side of the metallic mirror layer 32 facing away from the semiconductor layer sequence 1, a layer sequence 34 with one or more protective layers is arranged, which is electrically conducting and which protects the layers lying above it in the illustration shown. Thus, as is indicated in FIG. 1, the metallic mirror layer 32 can be retracted in the lateral direction from the later chip edge, which lies in the region of the singulation line 99, and thus be completely covered with the layer sequence 34 as seen from the semiconductor layer sequence 1 and thereby encapsulated. This can be particularly advantageous if a material such as silver, which is sensitive to oxygen and/or moisture, is used for the metallic mirror layer 32. In the case of an insensitive metallic mirror layer 32, for example made of gold, it may also be possible for the metallic mirror layer 32 to extend to the edge of the chip.

For example, the layer sequence 34, as viewed from the metallic mirror layer 32 in the direction of the carrier substrate 2, may also have one or more protective layers that can serve as protection for the reflective layers arranged above it.

The reflective layer 3 with the via 4 is selected in such a way that the greatest possible reflectivity and at the same time the best possible electrical connection can be achieved on the rear surface 13 of the semiconductor layer sequence 1. However, the layers and structures described are only to be understood as a preferred embodiment and not as limiting.

The following process steps are described purely by way of example using the structure shown in FIG. 1. For the sake of clarity, not all previously described layers and structures are provided with reference numerals.

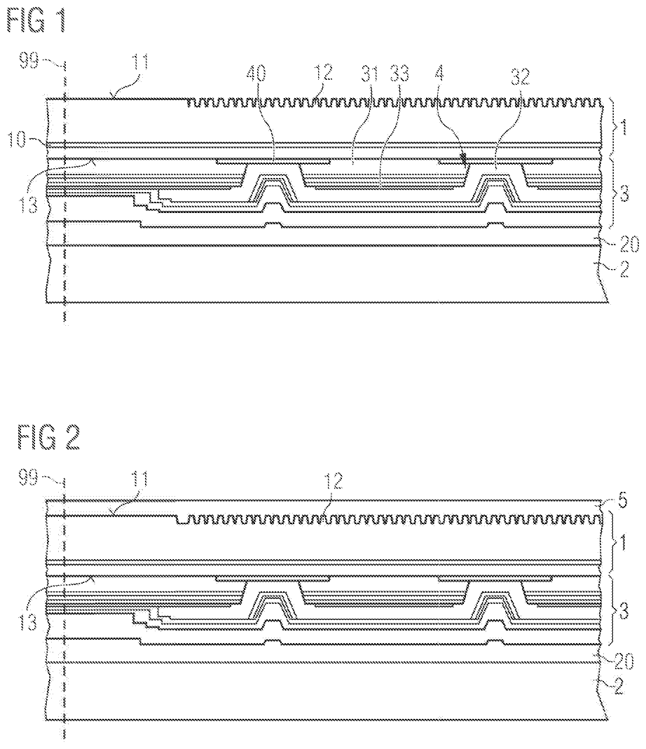

As shown in FIG. 2, a planarization layer 5 is applied across a large area of the light-outcoupling surface 11. In particular, the planarization layer 5, as shown in FIG. 2, can be applied directly to the light-outcoupling surface 11 and thus directly to the light-outcoupling structure 12. The planarization layer 5 can, for example, comprise or be made of an oxide, nitride or oxynitride. Particularly preferably, a material is used for the planarization layer 5 that is transparent and has a refractive index that is smaller than the refractive index of the semiconductor layer sequence 1 at the light-outcoupling surface 11. In the embodiment shown, the planarization layer 5 has silicon dioxide or is preferably of silicon dioxide.

The planarization layer 5 can be deposited, for example, by chemical vapor deposition, such as with TEOS or silane, by sputtering or by spin-on, such as spin-on-glass. A polishing method such as a CMP method can be used to planarize the surface of the planarization layer material facing away from the semiconductor layer sequence 1, so that instead of the surface structure of the light-outcoupling surface 11 formed by the light-outcoupling structure 12, a surface that is as flat as possible can be made available for the further method steps. If necessary, the planarization layer 5 can also be sintered.

A filter layer and a contact structure are applied to the planarization layer 5, as described below. For this purpose, as explained in connection with FIGS. 3A to 3E, the filter layer can be applied before the contact structure is applied.

As shown in FIG. 3A, the filter layer 6 can be deposited, preferably directly and further preferably across a large area and unstructured, on the planarization layer 5, for example by vapor deposition, sputtering or ion plating. The filter layer 6 can particularly preferably be a filter based on or in the form of a Bragg mirror, which for example has dielectric layers with or made of silicon dioxide and niobium pentoxide. Other materials and material combinations are also possible. In particular, the filter layer 6 can be adapted to the planarization layer 5 and possibly other layers such as passivation layers in terms of layer thicknesses and materials. In addition, the filter layer 6 can be adapted to the intended use in terms of its optical properties, for example to a material and/or optical element arranged above it, such as a silicone lens. The mirror design of the filter layer 6 can be optimized in order to reduce the overall thickness and thus reduce the process times for coating and the other process steps described below. Furthermore, the mirror design of the filter layer 6 can be optimized to improve the stability of the method and of control mechanisms and to reduce the susceptibility to deviations.

The layers of the filter layer 6 can each have a layer thickness, in particular an optical layer thickness, which is preferably selected as a function of the wavelength of the light generated in the active layer and the refractive index of the material used in each case such that the filter layer 6 has the effect that instead of the radiation characteristic at the light-outcoupling surface 11, which can in particular be a Lambertian radiation characteristic, there is a more forward radiation characteristic downstream of the filter layer 6.

After applying the filter layer 6, a mesa etching can be carried out in the region of the singulation lines 99 for chip definition, as shown in FIGS. 3B and 3C. For this purpose, a mask 90, for example a resist mask, is applied to the filter layer 6 in the region in which no mesa etching is to take place, as shown in FIG. 3B.

The filter layer 6 and the planarization layer 5 in the region not covered by the mask 90 can be opened, for example, by wet-chemical means, such as with HF, or by dry-chemical means, such as with a fluorine-based plasma, or by a combination thereof. Removal of the semiconductor layer sequence 1 can also be performed wet-chemically and/or dry-chemically. After mesa etching, stripping can be carried out to remove the mask 90. Furthermore, as shown in FIG. 3C, a passivation layer 7, for example with or made of silicon nitride, can be deposited. Alternatively, it is also possible that no passivation layer is applied.

The mesa trenches 14 generated by the mesa etching preferably form a grid of intersecting linear depressions in the wafer composite, through which the semiconductor chips are defined that can later be separated by singulation. As can be seen in FIG. 3C, the mesa trenches are free of the material of the filter layer 6, so that during singulation only the layers below the semiconductor layer sequence 1 as seen from the carrier substrate 2 have to be separated with the carrier substrate 2.

In a further process step, a contact structure is applied to the light-outcoupling surface 11 from the light-outcoupling surface as shown in FIGS. 3D and 3E in order to ensure that the semiconductor layer sequence 1 can be contacted electrically. For this purpose, the filter layer 6 and the planarization layer 5 and, if present, the passivation layer 7 are opened in order to expose the upper side of the semiconductor layer sequence 1, i.e., the light-outcoupling surface 11, in the region in which the contact structure is to be applied. Thus, for each semiconductor chip that is subsequently singulated, at least one opening is produced in the region in which the contact structure is to be applied. The opening 60 forms an essentially negative shape to the contact structure to be applied. In the embodiment shown, an opening 60 is formed in the planarization layer 5, the filter layer 6 and the passivation layer 7 by means of a mask 91 and photographic technique as well as dry-chemical etching, for example with fluorine-based plasma, and/or wet-chemical etching, for example with HF, as shown in FIG. 3D. Even if the mask 91 is only indicated above the filter layer 6 in FIG. 3D, it can also be located in the mesa trenches 14.

After the opening 60 has been produced, the material for the contact structure is applied over the mask 91 and in particular into the opening 60, for example by vapor deposition and/or sputtering. By removing the laquer, i.e., removing the mask 91 with the contact structure material applied to it, only the contact structure 8 remains in the opening 60 provided for this purpose, as shown in FIG. 3E. If necessary, an additional etch-stop layer can be applied to the contact structure 8 beforehand. If necessary, sintering can also be carried out.

The contact structure 8 can be single-layered or multi-layered and can, for example, have one or more materials such as Au, Ge and Ni and, above these, Ti, Pt, Au in the form of an alloy contact.

A contact layer 9 can be applied to the underside of the carrier substrate 2 opposite the semiconductor layer sequence 1, by means of which electrical contacting is possible from the side opposite the contact structure 8. The contact layer 9 can, for example, be made of Au or be applied across a large area. By means of the contact layer 9, the subsequently completed light-emitting semiconductor chip can be soldered or preferably glued, for example with a silver conductive adhesive, to a carrier such as a circuit board or a light-emitting diode housing and thus mounted and electrically connected.

The opening 60, in which the contact structure 8 is applied, can be larger than the contact structure 8 in terms of lateral expansion, as can be seen in FIG. 3E, so that the contact structure 8 is spaced laterally from the planarization layer 5, the filter layer 6 and the passivation layer 7 in the embodiment shown. This means that after the contact structure 8 has been applied, there may be a gap between the contact structure 8 and the layers already present before the contact structure 8 is applied. The light-outcoupling surface 1 can thus be exposed in the opening 60 in a region between the contact structure 8 and the planarization layer 5, the filter layer 6 and the passivation layer 7. The width of the opening 60 can be adjusted by the mask 91 and by the etching process(es) used. Dry-etching can make the opening 60 rather narrow due to the essentially directional etching effect, whereas wet-etching under-etches the layers under the mask 91 to a certain extent and the opening 60 can thus be formed with a somewhat larger lateral width. Typically, the exposed region can have a width of 0.5 μm to 2 μm or up to 5 μm or even up to 10 μm.

As an alternative to the previously described structuring of the filter layer 6 applied across a large area, it can also be recessed directly in the regions where the contact structure 8 is to be applied, for example using a lift-off method. This means that the comparatively thick filter layer 6 does not have to be opened in an etching process.

After the contact structure 8 has been applied, the wafer composite is singulated along the singulation lines 99 in the mesa trenches 14 into individual light-emitting semiconductor chips. In FIG. 4, a light-emitting semiconductor chip 100 is shown in a top view onto the filter layer 6 and thus against the preferred direction of emission of the light generated in the semiconductor layer sequence during operation by the filter layer 6. Particularly preferably, as can be seen in FIG. 4, the contact structure 8 can form a current distribution structure in order to achieve the most uniform possible current distribution from the side of the light-outcoupling surface into the semiconductor layer sequence. For this purpose, the contact structure 8 can preferably have a plurality of contact webs 81. Furthermore, the contact structure 8 can have a connection region 82, via which the contact structure 8 can be contacted from the outside. For example, the connection region 82 can be intended and configured to be contacted by one or more bonding wires. The connection region 82 can thus, for example, be a bonding pad onto which one or more bonding wires, for example four bonding wires, can be bonded. In the embodiment shown, the contact webs 81 are embodied as contact fingers, which may, for example, be spaced at a distance of around 100 μm from one another and which extend away from the connection region 82 over the light-outcoupling surface. The filter layer 6 is present between the contact webs 81, while the chip edge has the structure generated by the mesa trenches 14. Using the method described above, the entire contact structure 8 can be uncovered and thus exposed at the light-outcoupling surface. Compared to the modification of the method described below, a higher efficiency can be achieved as the filter layer 6 does not remain in the region of the contact structure 8.

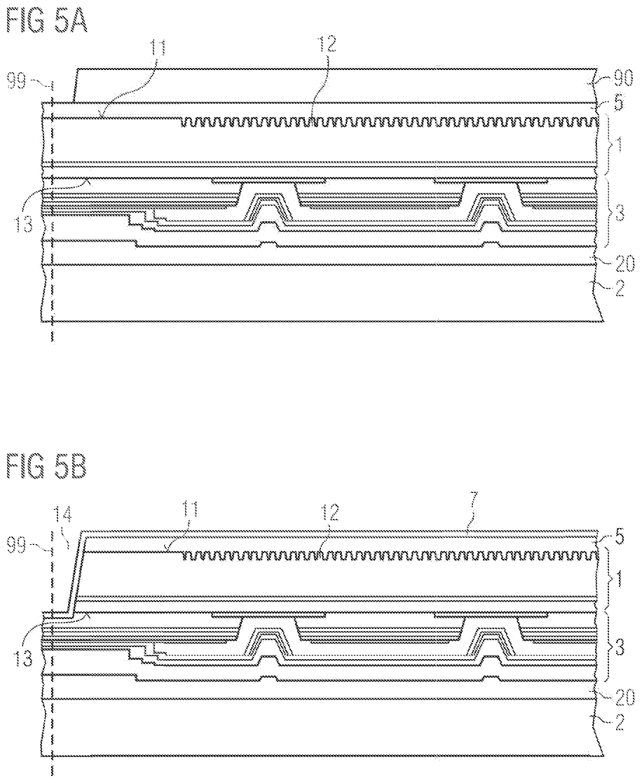

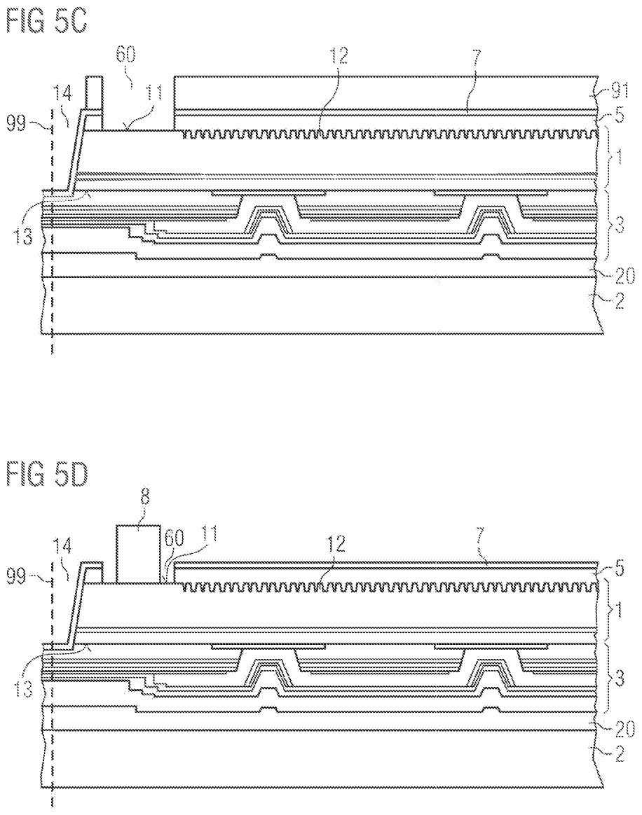

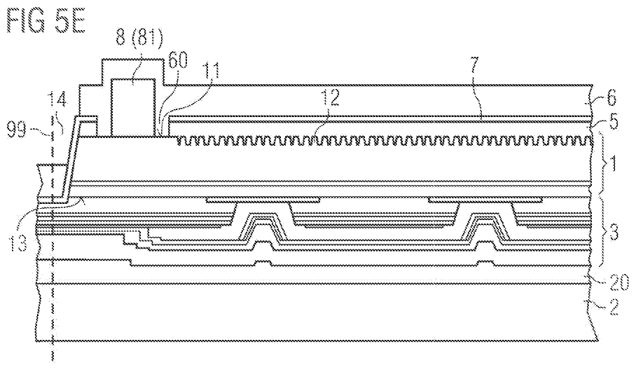

In connection with FIGS. 5A to 5E, method steps according to a further embodiment are shown, which represent a modification of the method described above. The following description therefore essentially relates to the differences from the method described above. In comparison with the process steps shown in connection with FIGS. 3A to 3E, the process steps described in connection with FIGS. 3B and 3C are carried out, as shown in FIGS. 5A and 5B, after the application of the planarization layer 5 shown in connection with FIG. 2, namely the application of a mask 90 to define the mesa trenches, the formation of the mesa trenches 14 and the application of the passivation layer 7. The features described in connection with FIGS. 3B and 3C also apply to the process steps shown in FIGS. 5A and 5B. The passivation layer 7 may also not be present or may be applied at a later stage.

In further process steps shown in FIGS. 5C and 5D, the planarization layer 5 and the passivation layer 7 are opened using a mask 91 to expose the top surface of the semiconductor layer sequence 1, i.e., the light-outcoupling surface 11, in the region where the contact structure 8 is to be applied. The features described in connection with FIGS. 3D and 3E also apply to the process steps shown in FIGS. 5C and 5D, wherein an etch stop layer can also be applied over the entire surface if required. The contact layer 9 described above in connection with FIG. 3E can also be applied at a later stage, as shown below in connection with FIG. 6B.

In a further process step, as shown in FIG. 5E, the filter layer 6 is applied over the contact structure 8, the planarization layer 5 and the passivation layer 7. The features described in connection with FIG. 3A also apply to the process step shown in FIG. 5E.

As described above in connection with FIG. 3E, the opening 60 generated in the planarization layer 5 and the passivation layer 7 prior to the application of the contact structure 8 may have a larger lateral width than the contact structure 8, so that the planarization layer 5 and the passivation layer 7 are laterally spaced from the contact structure 8 and, after the application of the contact structure 8, there is a space between the contact structure 8 and the planarization layer 5 and the passivation layer 7 in the lateral direction, the size of which may depend on the etching method used to produce the opening 60. Compared to the method steps of FIGS. 3A to 3E, in the modification of the method shown in FIGS. 5A to 5E, the interspace and thus the exposed region of the light-outcoupling surface 11 can be covered with the filter layer 6, as can be seen in FIG. 5E. As a result, the filter layer 6 can serve as a passivation or protective layer for the exposed light-outcoupling surface 11. In other words, the filter layer 6 can be applied directly to the light-outcoupling surface 11 of the semiconductor layer sequence 1 in a region between the contact structure 8 and the planarization layer 5 and thus be in direct contact with the semiconductor material of the semiconductor layer sequence 1.

Furthermore, the contact webs of the contact structure are arranged under the filter layer and are thus covered by the filter layer, so that the filter layer can also serve as a passivation or protective layer for the contact webs. The part of the contact structure 8 shown in FIG. 5E can therefore be a contact web 81, as indicated in the figure.

In order to be able to electrically connect the contact structure 8 from the outside, in further process steps, as shown in FIGS. 6A and 6B, a mask 92 can be applied to the filter layer 6 by means of photographic technology and structured in such a way that at least part of the connection region 82 can be exposed. To create an opening 61 in the filter layer 6, a dry chemical etching process can be used in the mask opening provided for this purpose, for example, to remove the filter layer 6 in the desired region and expose the contact structure 8. In order to avoid etching directly onto the metal of the contact structure 8 when opening the filter layer 6, an additional etch stop layer can be applied as an additional protective layer, for example made of or with Al O₂₃ or ITO, directly after the contact structure has been applied over it. In this case, dry-chemical etching can be carried out up to the etch stop layer and then wet-chemical etching can be used to etch through the etch stop layer to the contact structure 8. The mask 92 can then be removed by paint stripping.

By applying the filter layer 6 over the contact structure 8, it can be achieved that the filter layer 6 forms an additional protective layer on the top side of the light-emitting semiconductor chip, so that there is no exposed surface region of the semiconductor layer sequence 1 in the finished semiconductor chip. Furthermore, the filter layer 6, which is relatively thick in relation to the other layers described, only has to be opened once, so that the comparatively complex etching process required for this does not have to be carried out several times.

As described above in connection with FIG. 3E, a contact layer 9 can be applied to the side of the carrier substrate facing away from the semiconductor layer sequence 1, as indicated in FIG. 6B.

As can be seen in FIGS. 5E to 6B, the filter layer 6 can also be applied across a large area in the mesa trenches 14 and remain there, for example. In this case, after singulation into individual light-emitting semiconductor chips, the semiconductor layer sequence 1 is surrounded at the edge of the chip by the filter layer 6, which can thus act as a lateral passivation or protective layer.

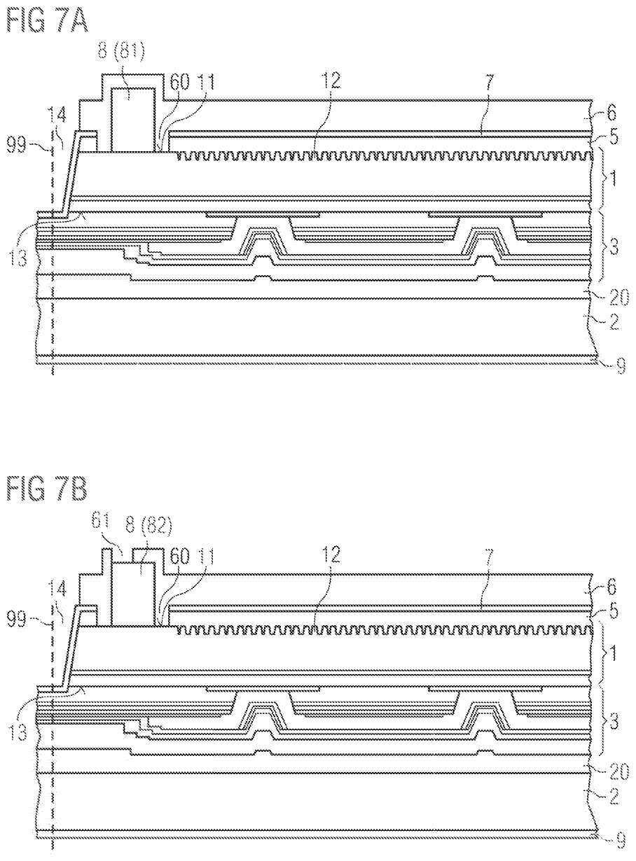

Alternatively, as shown in FIG. 7A in the region of a contact web 81 and in FIG. 7B in the region of the connection region 82, the filter layer can also be removed in the mesa trench 14 and thus at the chip edge in the subsequently completed light-emitting semiconductor chip. This can be done by a suitable mask 92 during the previously described production of the opening above the connection region 82 or also in a separate masking process.

The features and embodiments described in connection with the figures can be combined with one another according to further embodiments, even if not all combinations are explicitly described. Furthermore, the embodiments described in connection with the figures may alternatively or additionally have further features as described in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

1. A light-emitting semiconductor chip comprising:
a semiconductor layer sequence with an active layer which is intended and configured for generating light and outcoupling the light via a light-outcoupling surface during operation,
a filter layer deposited on the light-outcoupling surface and
a contact structure, which is deposited on the light-outcoupling surface in a region that is free of the filter layer,
wherein the contact structure is applied directly to the semiconductor layer sequence,
wherein the filter layer has an opening in which the contact structure is arranged and which forms a substantially contiguous negative shape to the contact structure, and
wherein the filter layer is a dielectric angle filter.

2. (canceled)

3. The semiconductor chip according to claim 1, wherein the contact structure comprises a plurality of contact webs.

4. The semiconductor chip according to claim 3, wherein the contact webs are covered by the filter layer on a side facing away from the semiconductor layer sequence.

5. The semiconductor chip according to claim 3, wherein the contact webs on a side facing away from the semiconductor layer sequence are at least partially free of the filter layer.

6. The semiconductor chip according to claim 1, wherein the contact structure comprises a connection region which is at least partially free of the filter layer on a side facing away from the semiconductor layer sequence.

7. The semiconductor chip according to claim 1, wherein the semiconductor layer sequence comprises a light-outcoupling structure at the light-outcoupling surface.

8. The semiconductor chip according to claim 7, wherein a planarization layer is deposited directly to the light-outcoupling structure.

9. The semiconductor chip according to claim 8, wherein the filter layer is arranged directly on the planarization layer.

10. The semiconductor chip according to claim 8, wherein a passivation layer is arranged between the filter layer and the planarization layer.

11. The semiconductor chip according to claim 8, wherein the contact structure is arranged in an opening of the planarization layer.

12. The semiconductor chip according to claim 11, wherein the contact structure is spaced from the planarization layer.

13. The semiconductor chip according to claim 12, wherein the filter layer is applied directly to the light-outcoupling surface in a space between the contact structure and the planarization layer.

14. The semiconductor chip according to claim 1, wherein the contact structure is spaced from the filter layer.

15. The semiconductor chip according to claim 14, wherein the light-outcoupling surface is exposed in the opening in a region between the contact structure and the filter layer.

16. The semiconductor chip according to claim 1, wherein a passivation layer is applied to the filter layer.

17. A method for manufacturing a light-emitting semiconductor chip according to claim 1, comprising:
providing a semiconductor layer sequence with an active layer which is intended and configured for generating light and outcoupling the light via a light-outcoupling surface during operation,
depositing a filter layer on the light-outcoupling surface and
depositing of a contact structure on the light-outcoupling surface in a region that is free of the filter layer.
